(19) United States
(12) Patent Application Publication
(10) Pub. No.: US 2005/0068741 A1
(43) Pub. Date: Mar. 31, 2005

(54) System and method for mounting processor and heat transfer mechanism

(76) Inventors: Douglas A. Bailey, Concord, MA (US); Nicholas J. Palmer, Rutland, MA (US); Peter M. Martino, Windham, NH (US)

Correspondence Address: HEWLETT-PACKARD COMPANY;Intellectual Property Administration, P.O. Box 272400, Fort Collins, CO, 80527-2400, US

(21) Appl. No.: 10/674,011

(22) Filed: Sep. 29, 2003

(51) Int. Cl. H05K 7/20

(52) U.S. Cl. 361/719

(57) ABSTRACT

A heat sink having a base structure with a protruding thermal interface having an arcuate surface adapted to contact a processor assembly. The arcuate surface is adapted to accommodate a bent configuration of the base structure induced by a mounting load applied to the base structure.

### BACKGROUND OF THE RELATED ART

Processor chips, such as a central processing unit (CPU), are employed in a variety of systems and devices, such as consumer computers, servers, manufacturing systems, and other industrial applications. In some of these systems and devices, the processor chip is coupled to a circuit board and a heat sink, which facilitates heat transfer away from the processor chip to maintain a desired operating temperature. Certain processor chips have a large number of electrical contact pads, which engage mating contact pads on the circuit board. The heat sink is mounted over the processor chip on the circuit board with threaded fasteners outside the four corners of the processor chip. Given the large number of contact pads, a considerable amount of force is applied to the heat sink to achieve a connection between all contact pads. Unfortunately, the applied force causes the heat sink to bend or bow, thereby subjecting the processor chip to mechanical stresses and reducing the contact area between the heat sink and the processor chip.

### BRIEF DESCRIPTION OF THE DRAWINGS

Advantages of one or more disclosed embodiments may become apparent upon reading the following detailed description and upon reference to the drawings in which:

FIG. 1 is an exploded perspective view of a processor-based system in accordance with certain embodiments of the present invention;

FIG. 2 is a side view of a processor mounting system in accordance with certain embodiments of the present invention;

FIG. 3 is a partial side view of the processor mounting system of FIG. 2 illustrating an incomplete interface between a processor and a heat sink before applying a mounting force to the heat sink; and

FIG. 4 is a partial side view of the processor mounting system of FIG. 2 illustrating an alternative embodiment having a complete interface between the processor and the heat sink after applying the mounting force to the heat sink.

### DETAILED DESCRIPTION

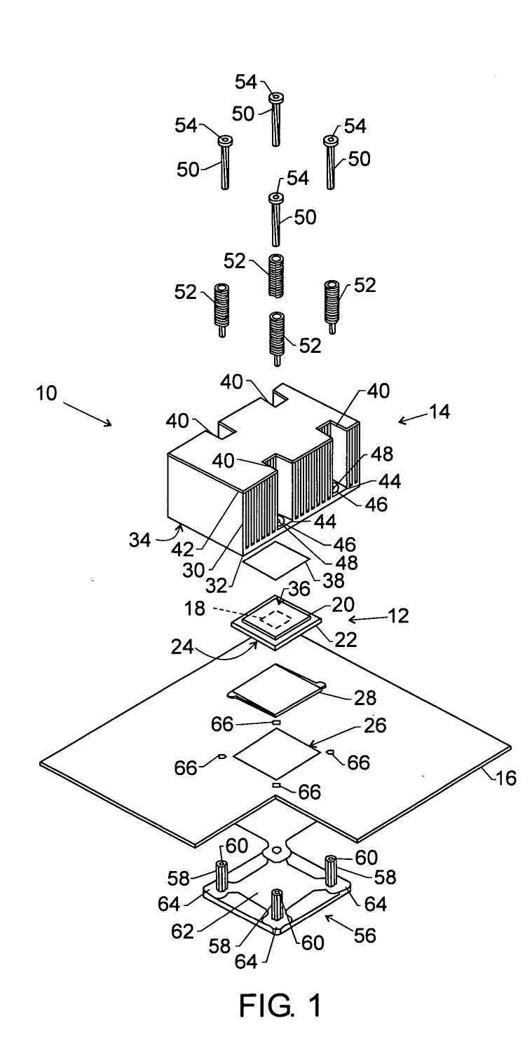

FIG. 1 is an exploded perspective view of a processor-based system 10 in accordance with certain embodiments of the present invention. As illustrated, the processor-based system 10 comprises a processor assembly or chip package 12, a heat transfer structure or heat sink 14, and a circuit board 16 (e.g., a motherboard). The illustrated chip package 12 comprises a microprocessor die or processor chip 18 disposed between a lid or heat spreader 20 and a base or substrate 22. At a bottom surface of the substrate 22, the chip package 12 has a plurality of contact pads 24 for electrical contact with mating contact pads 26 on the circuit board 16. However, other suitable chips and packages are also applicable to the processor-based system 10. In the illustrated embodiment, the processor-based system 10 also comprises an electrical interposer 28 disposed between the contact pads 24 and the mating contact pads 26 to facilitate an electrical connection between each respective pair of contact pads 24 and 26. As discussed in further detail below, the electrical interposer 28 comprises a plurality of conductive springs, compressible members, or projecting structures, which ensure contact between the contact pads 24 and 26.

The heat sink 14 illustrated in FIG. 1 comprises a plurality of heat transfer members or fins 30 extending from a base structure 32 having a bottom surface 34, which is mountable over a top surface 36 of the chip package 12. As illustrated, a thermal interface 38 is also positioned between the bottom surface 34 of the heat sink 14 and the top surface 36 of the chip package 12. For example, the thermal interface 38 may comprise a phase change thermal interface material. As the phase change thermal interface material is heated above its melting point, the interface material flows into the pores of the bottom surface 34 and top surface 36 to improve the conductive path between the heat sink 14 and the chip package 12.

The illustrated heat sink 14 also comprises a set of mounting slots 40 extending through a top 42 of the heat sink 14, through the fins 30, and to the base structure 32. At a bottom 44 of each mounting slot 40, the heat sink 14 also has a bearing member or support pad 46 disposed about a mounting receptacle 48. These support pads 46 can be loosely mounted, press-fit into place, or mounted by other suitable mounting techniques. As illustrated, the set of mounting slots 40 are adapted to receive a set of externally threaded fasteners 50 jacketed by coil springs 52. In assembly, the externally threaded fasteners 50 extend through the mounting receptacles 48 and the coil springs 52 provide a resistive force between the mounting pads 46 and a head 54 of the externally threaded fasteners 50. The support pads 46 also provide a hard bearing surface for the coil springs 52. For example, the support pads 46 may comprise steel washers or any other suitable rigid bearing structure. The support pads 46 also prevent the coil springs 52 from gouging, chipping, or catching on the bottom 44 of the mounting slots 40. In this manner, the support pads 46 prevent corruption of the system 10 by flakes or chips from the heat sink 14.

Assembly of the processor-based system 10 also may be improved with one or more lubricants. In certain embodiments, the externally threaded fasteners 50 are coated with a dry lubricant, such as molybdenum disulfide. For example, the lubricant material may be sprayed onto the externally threaded fasteners 50 and subsequently baked to provide a dry lubricant coating. Alternatively, the externally threaded fasteners 50 may be dipped or immersed in the lubricant material followed by a subsequent curing process. With this dry lubricant, the externally threaded fasteners 50 can be more easily threaded under high loads. In addition, the dry lubricant does not corrupt or pollute the surfaces of the components being coupled together.

As illustrated in FIG. 1, the processor-based system 10 also comprises a chassis or outer support structure 56 for mounting the chip package 12 and the heat sink 14 to the circuit board 16. The illustrated outer support structure 56 comprises a set of mounting posts 58 each having a mating fastener 60, which can be engaged by the externally threaded fastener 50. The outer support structure 56 also has a central flat portion 62, which tapers off to lowered portions 64 adjacent the mounting posts 58. For example, the central flat portion 62 can be machined, lapped, honed, and/or generally smoothed to a substantially flat surface. In operation, the central flat portion 62 provides uniform support for the chip package 12 mounted to the circuit board 16, thereby improving the electrical contact between contact pads 24 and 26 and reducing mechanical stresses in the components.

In assembly, the mounting posts 58 of the outer support structure 56 are extended through receptacles 66 in the circuit board 16 around the perimeter of the mating contact pads 26. The chip package 12 is then lowered onto the circuit board 16 with the electrical interposer 28 disposed between the contact pads 24 and 26. In turn, the heat sink 14 is lowered onto the chip package 12 with the thermal interface 38 between the bottom surface 34 of the heat sink 14 and the top surface 36 of the chip package 12. The externally threaded fasteners 50 (jacketed with the coil springs 52) are then inserted through the mounting receptacles 48 of the heat sink 14 for engagement with the mating fasteners 60 of the mounting posts 58. Finally, the externally threaded fasteners 50 are rotated until a desired compressive force is applied between the assembly of the heat sink 14, the chip package 12, the circuit board 16, and the outer support structure 56. For example, a compressive force ranging between 100 and 300 pounds may be applied to some embodiments of the processor-based system 10. In certain embodiments, a compressive force of approximately 250 pounds or greater may be applied to the foregoing assembly. However, any suitable force can be applied to the assembly depending on the particular configuration, dimensions, number of contact pads 24, and so forth.

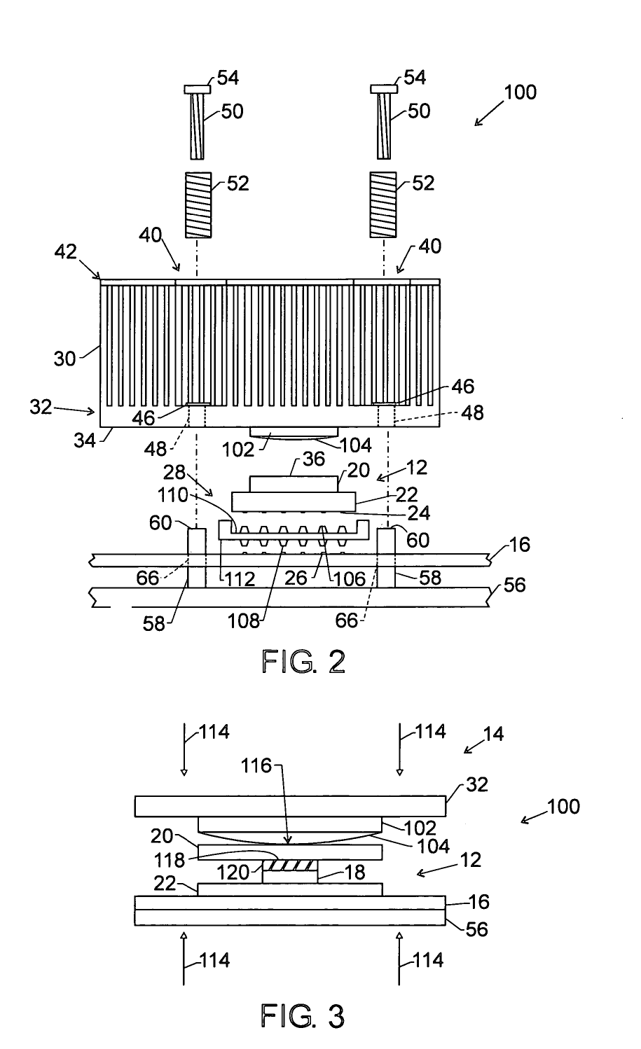

FIG. 2 is a partial side view of the processor-based system 10 of FIG. 1 illustrating a processor mounting system 100 in accordance with certain embodiments of the present invention. In the illustrated embodiment, the bottom surface 34 of the heat sink 14 comprises a projecting structure or boss 102 having a generally curved or arcuate outer crown 104. For example, the boss 102 may comprise a copper material, which is machined and then coined to form the arcuate outer crown 104. However, any other suitable materials and manufacturing processes can be used to form the boss 102 and the arcuate outer crown 104. In addition, the arcuate outer crown 104 may comprise a variety of curvatures, such as a generally spherical, cylindrical, or convex surface structure.

In operation, the boss 102 provides additional support or rigidity in the region of mounting to the chip package 12, thereby reducing bending of the heat sink 14 and reducing stresses on the chip package 12. In this manner, the boss 102 also maintains better contact between the bottom surface 34 of the heat sink 14 and the top surface 36 of the chip package 12. The arcuate outer crown 104 further improves the foregoing characteristics of the boss 102. For example, in assembly, the arcuate outer crown 104 accommodates bending of the heat sink 14 and the boss 102 to maintain greater contact (e.g., substantially full contact) between the bottom surface 34 and the top surface 36. Accordingly, the increased contact area between the heat sink 14 and the boss 102 facilitates improved heat transfer away from the chip package 12 and out through the fins 30. The arcuate outer crown 104 also functions to distribute the load applied by the externally threaded fasteners 50 over the increased contact area. In certain embodiments, the arcuate outer crown 104 comprises a semi-spherical surface having a radius substantially matched with a bending radius of the base structure 32 during assembly. However, other embodiments of the arcuate outer crown 104 may comprise a convex surface tailored to a particular chip package 12, loading force, and desired contact interface between the arcuate outer crown 104 and the heat spreader 20.

As further illustrated in FIG. 2, the electrical interposer 28 comprises a plurality of conductive springs or projecting members 106 and 108 disposed on upper and lower surfaces 110 and 112, respectively. These projecting members 106 and 108 may comprise any suitable conductive and compressible material and structure, such as conductive metal particles suspended in a polymer, a solid metal spring, or a mass of compressed metal wire. After assembly, the conductive springs or projecting members 106 provide continuous contact with the contact pads 24 on the chip package 12, while the conductive springs or projecting members 108 provide continuous contact with the contact pads 26 on the circuit board 16. As noted above, certain embodiments of the processor mounting system 100 may mount the chip package 12 directly on the circuit board 16, thereby placing the contact pads 24 and 26 in direct contact with one another.

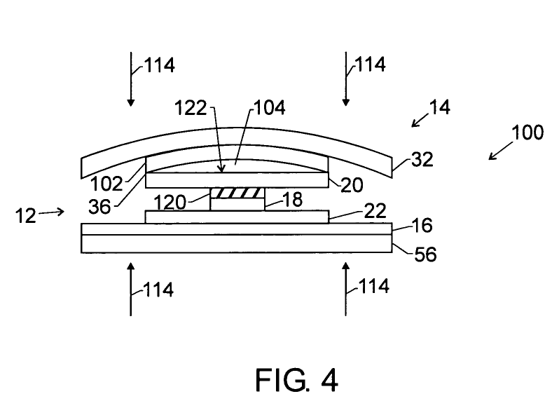

FIGS. 3 and 4 further illustrate the processor mounting system 100 illustrated in FIG. 2 in accordance with certain embodiments of the present invention. Engagement between the externally threaded fasteners 54 and the mating fasteners 60 (see FIG. 2) create a compressive loading or mounting force 114 extending through the base structure 32 of the heat sink 14, the chip package 12, the electrical interposer 28, the circuit board 16, and the outer support structure 56. FIG. 3 is a partial side view of the processor mounting system 100 illustrating a partial interface or contact 116 between the arcuate outer crown 104 and the lid or heat spreader 20 of the chip package 12. In certain embodiments, the partial interface or contact 116 is centered on the heat spreader 20, such that the mounting force 114 is distributed substantially over the processor chip 18 disposed between the heat spreader 20 and the substrate 22. In the illustrated embodiment, the processor chip 18 is coupled to a central region 118 of the heat spreader 20 by a bonding material or adhesive 120, such as an epoxy. Accordingly, the heat spreader 20 overhangs or extends beyond the perimeter of the processor chip 18. Given this overhang, the heat spreader 20 is particularly vulnerable to bending. By focusing the mounting force 114 on the central region 118, the arcuate outer crown 104 substantially reduces bending of the heat spreader 20 and provides a substantially uniform distribution of the mounting force 114 on the processor chip 18. In this manner, the processor-based mounting system 100 reduces stresses and improves heat transfer away from the processor chip 18 and out through the heat sink 14.

In other embodiments, the processor mounting system 100 distributes the mounting force 114 over a greater surface area than the central region 118. FIG. 4 is a partial side view of the processor mounting system 100 illustrating a substantially complete interface or increased surface contact 122 between the arcuate outer crown 104 and the lid or heat spreader 20 of the chip package 12. As illustrated, the mounting force 114 bows or bends the base structure 32 of the heat sink 14 in this mounted configuration of system 100. If the base structure 32 was flat rather than having the arcuate outer crown 104, then the mounting force would cause undesirable bending of the heat sink 14 and reduced contact between the heat sink 14 and the heat spreader 20 of the chip package 12. However, in the illustrated embodiment, the arcuate outer crown 104 accommodates the bending associated with the mounting force 114, thereby causing the arcuate outer crown 104 to bend resiliently to a flat or substantially flat geometry. As a result, the illustrated boss 102 contacts the top surface 36 of the heat spreader 20 over a greater surface area, e.g., the substantially complete interface or increased surface contact 122. Again, the increased surface contact 122 illustrated in FIG. 4 reduces stresses and improves heat transfer away from the processor chip 18 and out through the heat sink 14.

1. A heat sink, comprising:
a base structure comprising a protruding thermal interface having an arcuate surface adapted to contact a processor assembly, wherein the arcuate surface is adapted to accommodate a bent configuration of the base structure induced by a mounting load applied to the base structure.

2. The heat sink set forth in claim 1, wherein the arcuate surface is substantially flat in the bent configuration.

3. The heat sink set forth in claim 1, comprising a plurality of heat transfer members extending from the base structure.

4. The heat sink set forth in claim 1, wherein the arcuate surface comprises a semi-spherical surface.

5. The heat sink set forth in claim 1, wherein the arcuate surface comprises a semi-cylindrical surface.

6. The heat sink set forth in claim 1, comprising a plurality of spring-loaded fasteners coupled to the base structure.

7. The heat sink set forth in claim 1, comprising a threaded fastener coupled to the base structure, wherein the threaded fastener comprises a dry lubricant.

8. The heat sink set forth in claim 7, wherein the dry lubricant comprises a molybdenum disulfide plating.

9. The heat sink set forth in claim 1, wherein the protruding thermal interface comprises copper.

10. A system, comprising:
a circuit board comprising a plurality of chip contacts;
a processor package comprising a plurality of contacts aligned with the plurality of chip contacts;
a heat sink comprising an arcuate surface extending from a base structure of the heat sink, wherein the processor package is compressively mounted between the circuit board and the arcuate surface.

11. The system set forth in claim 10, wherein the arcuate surface comprises a curvature substantially flattened by a bent configuration of the base structure.

12. The system set forth in claim 11, wherein the bent configuration is induced by a mounting load applied to the heat sink.

13. The system set forth in claim 10, further comprising an electrical interposer disposed between the processor package and the circuit board, wherein the electrical interposer comprises a compressible electrical contact extending from the plurality of contacts to the plurality of chip contacts.

14. The system set forth in claim 10, wherein the processor package comprises a heat spreader, a substrate having the plurality of contacts, and a processor disposed between the heat spreader and the substrate.

15. The system set forth in claim 14, wherein the heat spreader overhangs a perimeter of the processor.

16. The system set forth in claim 10, comprising a plurality of spring-loaded mounting fasteners coupled to the heat sink.

17. The system set forth in claim 10, comprising a plurality of threaded mounting fasteners coupled to the heat sink, wherein threads of the plurality of threaded mounting fasteners comprises a dry lubricant coating.

18. The system set forth in claim 10, comprising a thermal interface material disposed between the arcuate surface and the processor package.

19. A method of processor mounting, comprising:
aligning an arcuate surface of a heat sink adjacent a surface of a processor assembly; and
compressively mounting the processor assembly between the arcuate surface and a circuit board.

20. The method set forth in claim 19, wherein aligning the arcuate surface comprises centering a convex boss structure with a heat spreader of the processor assembly.

21. The method set forth in claim 19, wherein compressively mounting comprises bending the heat sink in a curvature opposite the arcuate surface.

22. The method set forth in claim 19, wherein compressively mounting comprises substantially flattening the arcuate surface.

23. The method set forth in claim 19, comprising positioning a thermal interface material between the arcuate surface and the surface of the processor assembly.
